(19) United States
(12) Patent Application Publication
(10) Pub. No.: US 2026/0206513 A1
(43) Pub. Date: Jul. 16, 2026

(54) SEMICONDUCTOR WAFER AND SEMICONDUCTOR WAFER PROCESSING METHOD

(71) Applicant: Mitsubishi Electric Corporation, Tokyo (JP)

(72) Inventors: Ryo FUNAKI, Tokyo (JP); Noriyuki YABUOSHI, Tokyo (JP)

(73) Assignee: Mitsubishi Electric Corporation, Tokyo (JP)

(21) Appl. No.: 19/395,789

(22) Filed: Nov. 20, 2025

(30) Foreign Application Priority Data
Jan. 14, 2025 (JP) 2025-004838

(51) Int. Cl. H01L 21/78; B24B 7/04; H01L 21/304

(52) U.S. Cl. CPC H10P 54/00; B24B 7/04; H10P 52/00

(57) ABSTRACT

A semiconductor wafer according to the present disclosure includes: a plurality of semiconductor devices; a plurality of scribe lines to divide the plurality of semiconductor devices into a plurality of semiconductor chips; and a grinding region provided along an outer peripheral portion and having a depth that is shallower than or the same as depths of the scribe lines.

### BACKGROUND

### Technical Field

The present disclosure relates to a semiconductor wafer and, in particular, to a semiconductor wafer whose damage by a solution used for wet etching has been suppressed.

### Description of the Background Art

A semiconductor wafer including semiconductor devices, such as LSIs, over a front surface thereof is divided into individual semiconductor chips after an entire back surface is ground to reduce a thickness. The semiconductor wafer undergoes a plurality of manufacturing steps before being divided into the semiconductor chips and has an outer peripheral surface arcuately chamfered to prevent breakage of the outer peripheral surface in the manufacturing steps. When a back surface of such a semiconductor wafer having an arcuately chamfered outer peripheral surface is polished to be thinned by grinding and the like, the arcuately chamfered portion might have a sharp knife edge. The semiconductor wafer thus might break during grinding or transport of the semiconductor wafer.

In Japanese Patent Application Laid-Open No. 2006-32661, an entire peripheral edge portion of an upper surface of a semiconductor wafer is cut to form a step while rotating the wafer on a chuck table, and then, after the upper surface of the wafer is covered with a protective film, a back surface of the semiconductor wafer is polished by grinding and the like. In this case, grinding is performed to reach a vertical surface of the step, so that an outer peripheral surface of the semiconductor wafer after grinding is the vertical surface and does not have a knife edge.

To divide the semiconductor wafer into individual chips, the semiconductor wafer includes a plurality of crisscrossing scribe lines in the upper surface thereof, and the scribe lines extend to an outer periphery of the wafer.

An attempt to process the back surface by wet etching after the protective film is disposed over the upper surface of the semiconductor wafer thus might cause ingress of an etching solution along the scribe lines to damage the semiconductor wafer.

### SUMMARY

It is an object of the present disclosure to provide a semiconductor wafer whose damage by an etching solution has been suppressed by preventing ingress of the etching solution from an end of the wafer.

A semiconductor wafer according to the present disclosure includes: a plurality of semiconductor devices; a plurality of scribe lines to divide the plurality of semiconductor devices into a plurality of semiconductor chips; and a grinding region provided along an outer peripheral portion and having a depth that is shallower than or the same as depths of the scribe lines.

The semiconductor wafer includes the grinding region provided along the outer peripheral portion and having the depth that is shallower than or the same as the depths of the scribe lines, so that the semiconductor wafer whose damage by an etching solution has been suppressed by preventing ingress of the etching solution from an end of the wafer when an upper surface is covered with a protective film can be obtained.

These and other objects, features, aspects and advantages of the present disclosure will become more apparent from the following detailed description of the present disclosure when taken in conjunction with the accompanying drawings.

### BRIEF DESCRIPTION OF THE DRAWINGS

FIG. 1 is a plan view of a semiconductor wafer according to the present disclosure when viewed from a side of an upper surface thereof;

FIG. 2 is a partial cross-sectional view of a semiconductor wafer according to Embodiment 1 of the present disclosure;

FIG. 3 is a partial cross-sectional view of the semiconductor wafer according to Embodiment 1 of the present disclosure;

FIG. 4 is a partial cross-sectional view of the semiconductor wafer according to Embodiment 1 of the present disclosure;

FIG. 5 is a partial perspective view illustrating an outer periphery of the semiconductor wafer before a grinding region is formed;

FIG. 6 is a partial perspective view illustrating the outer periphery of the semiconductor wafer including the grinding region;

FIG. 7 is a partial cross-sectional view of a semiconductor wafer according to Embodiment 2 of the present disclosure;

FIG. 8 is a partial cross-sectional view of the semiconductor wafer according to Embodiment 2 of the present disclosure;

FIG. 9 is a partial cross-sectional view of the semiconductor wafer according to Embodiment 2 of the present disclosure;

FIG. 10 is a partial perspective view illustrating the outer periphery of the semiconductor wafer including the grinding region;

FIG. 11 is a partial cross-sectional view of a semiconductor wafer according to Embodiment 3 of the present disclosure;

FIG. 12 is a partial cross-sectional view of the semiconductor wafer according to Embodiment 3 of the present disclosure;

FIG. 13 is a partial cross-sectional view of the semiconductor wafer according to Embodiment 3 of the present disclosure;

FIG. 14 is a partial perspective view illustrating the outer periphery of the semiconductor wafer including the grinding region;

FIG. 15 is a diagram schematically showing a cross section of a portion having a tapered surface of the semiconductor wafer;

FIG. 16 is a partial cross-sectional view of a semiconductor wafer according to a modification of Embodiment 3 of the present disclosure;

FIG. 17 is a diagram for describing a semiconductor wafer processing method according to Embodiment 4 of the present disclosure;

FIG. 18 is a diagram for describing the semiconductor wafer processing method according to Embodiment 4 of the present disclosure;

FIG. 19 is a diagram for describing a semiconductor wafer processing method according to Embodiment 5 of the present disclosure;

FIG. 20 is a diagram schematically showing a state of processing the semiconductor wafer in Embodiment 5 of the present disclosure;

FIG. 21 is a diagram showing a cross section of the tapered surface of the semiconductor wafer and control characteristics of a grinding wheel; and

FIG. 22 is a diagram schematically showing a state of processing a semiconductor wafer according to a modification of Embodiment 5 of the present disclosure.

### DESCRIPTION OF THE PREFERRED EMBODIMENTS

### Introduction

Embodiments of the present disclosure will be described below with reference to the accompanying drawings. The drawings are schematically shown, and sizes and positional correlations of images shown in different drawings are not necessarily accurate and can be changed as appropriate. In description made below, similar components bear the same reference signs and have similar names and functions. Detailed description thereof is thus sometimes omitted.

In description made below, terms referring to specific positions and directions, such as “upper”, “lower”, “side”, “bottom”, “front”, and “back”, are sometimes used, but these terms are used for the sake of convenience to facilitate understanding of details of the embodiments and do not relate to directions in actual implementation. In description made below, “outside” refers to a direction toward an outer periphery of a semiconductor wafer, and “inside” refers to a direction opposite “outside”.

### Embodiment 1

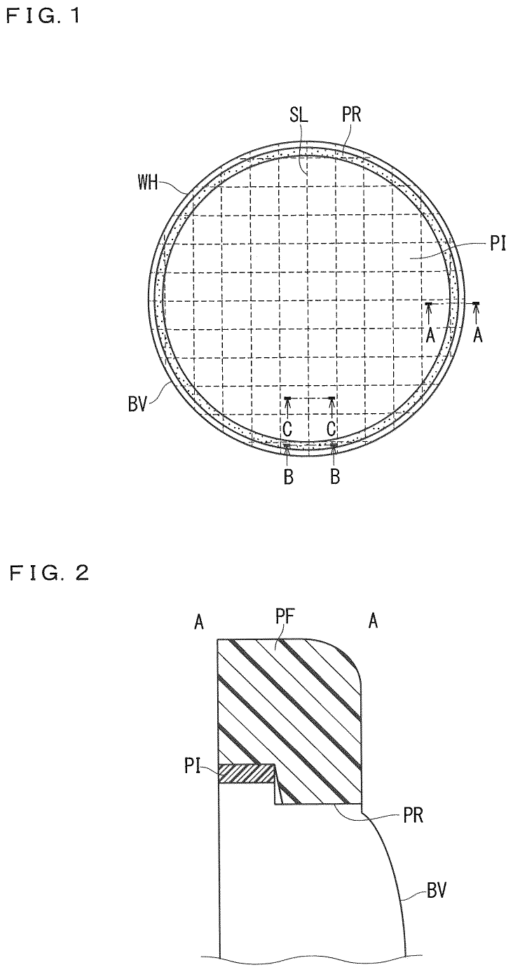

FIG. 1 is a plan view of a semiconductor wafer according to the present disclosure when viewed from a side of an upper surface thereof. As illustrated in FIG. 1, a semiconductor wafer WH according to the present disclosure includes a plurality of crisscrossing scribe lines SL in the upper surface, and the scribe lines SL extend to an outer periphery of the wafer. A top view of the semiconductor wafer is common to the other embodiments.

At the outer periphery of the semiconductor wafer WH, a grinding region PR is provided inside a wafer bevel portion BV and outside a polyimide region where a photosensitive polyimide film PI is disposed. The photosensitive polyimide film PI is disposed to protect semiconductor devices arranged over the upper surface of the semiconductor wafer WH, so that grinding of the semiconductor devices can be prevented by providing the grinding region PR outside the polyimide region. A grinding depth of the grinding region PR is shallower than depths of the scribe lines SL. A protective film disposed to cover the upper surface of the semiconductor wafer WH is omitted in FIG. 1 for the sake of convenience.

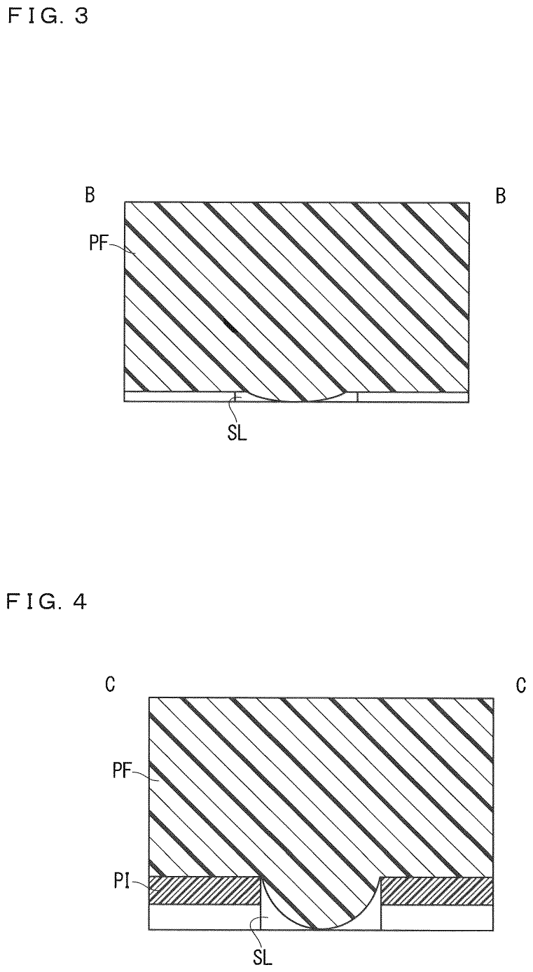

FIG. 2, FIG. 3, and FIG. 4 are cross-sectional views respectively taken along the line A-A, the line B-B, and the line C-C of FIG. 1. A protective film PF covering the upper surface of the semiconductor wafer WH is illustrated in each of FIGS. 2 to 4. FIGS. 2 to 4 illustrate portions in a direction of a thickness of the semiconductor wafer WH and illustrate only features of the semiconductor wafer WH according to Embodiment 1.

As indicated as the grinding region PR in each of FIGS. 2 and 3, a surface of an outer peripheral portion of the wafer is ground, so that a step between the grinding region PR and a bottom surface of each of the scribe lines SL can be reduced as illustrated in FIG. 3. Thus, when the protective film PF is adhered, a gap between the protective film PF entering the scribe line SL and the scribe line SL is reduced, and the protective film PF is in close contact with the scribe line SL as illustrated in FIG. 3. An area of close contact between the protective film PF and the scribe line SL thus increases to prevent ingress of water and an etching solution from the outer peripheral portion of the wafer into the scribe line SL, so that damage of the semiconductor wafer WH can be suppressed.

The protective film PF can be formed of a polyacrylic-based resin and has a sticky surface adhered to the semiconductor wafer WH. The material is not limited to the polyacrylic-based resin as long as the material is resistant to the etching solution when the semiconductor wafer WH is subjected to wet etching.

While the protective film PF is disposed over the photosensitive polyimide film PI in each of FIGS. 2 to 4, depending on the semiconductor wafer, the photosensitive polyimide film PI is not disposed, and the protective film PF is directly adhered to the semiconductor wafer.

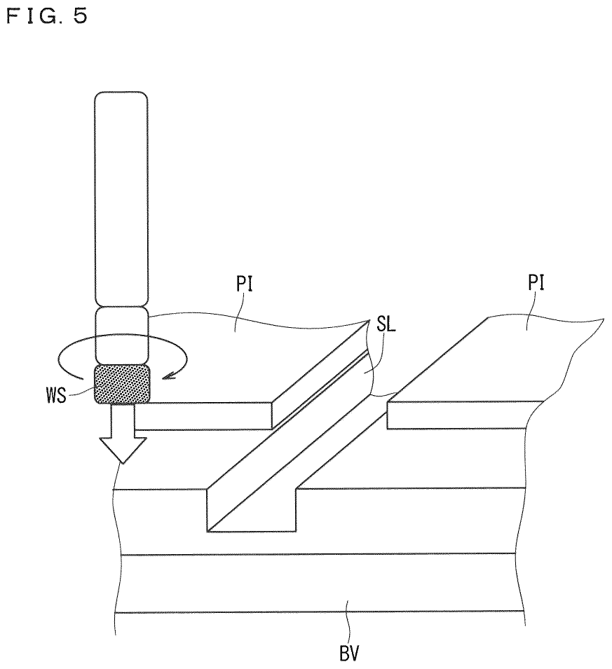

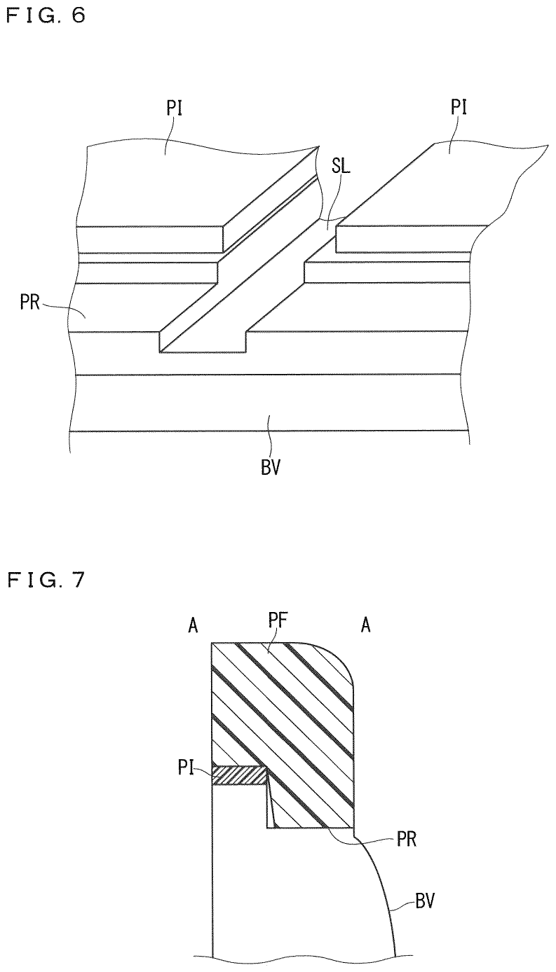

When the photosensitive polyimide film PI is disposed, the grinding region PR is formed after the photosensitive polyimide film PI is formed over the semiconductor wafer WH. FIGS. 5 and 6 are perspective views for describing a step of forming the grinding region PR.

FIG. 5 is a partial perspective view illustrating the outer periphery of the semiconductor wafer WH before the grinding region PR is formed, and a region of the semiconductor wafer WH outside the polyimide region where the photosensitive polyimide film PI is disposed is ground with a rotating grinding wheel WS.

FIG. 6 is a partial perspective view illustrating the outer periphery of the semiconductor wafer WH after the grinding region PR is formed, and the grinding region PR is formed to have a shallower depth than the scribe lines SL.

### Embodiment 2

While the grinding region PR provided at the outer periphery of the semiconductor wafer WH is formed to have a shallower depth than the scribe lines SL in Embodiment 1, the grinding region PR is provided to have the same depth as the scribe lines SL in the semiconductor wafer WH according to Embodiment 2.

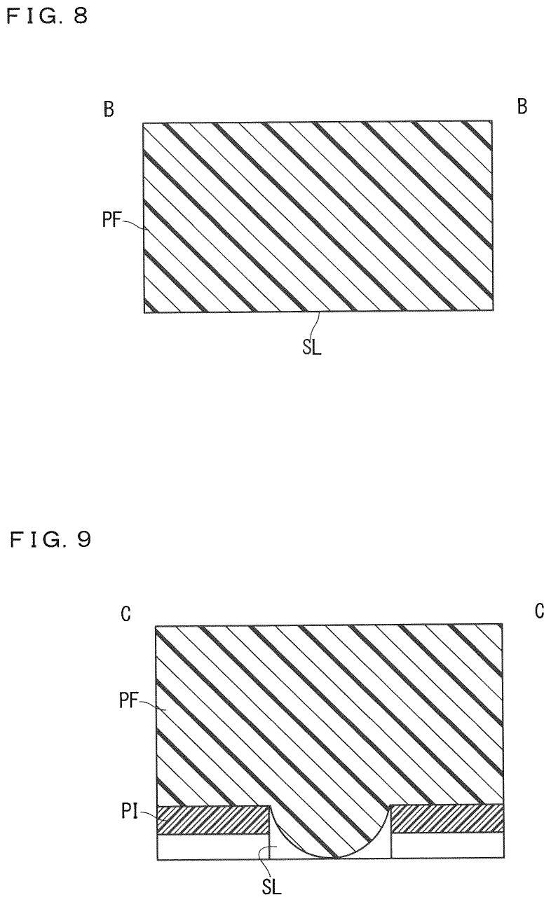

FIG. 7, FIG. 8, and FIG. 9 are cross-sectional views respectively taken along the line A-A, the line B-B, and the line C-C of FIG. 1. In FIGS. 7 to 9, the same components as those of the semiconductor wafer WH according to Embodiment 1 described with reference to FIGS. 2 to 4 bear the same reference signs as those of the same components, and redundant description is omitted.

As indicated as the grinding region PR in each of FIGS. 7 and 8, the surface of the outer peripheral portion of the wafer is ground, so that the step between the grinding region PR and the bottom surface of each of the scribe lines SL can be eliminated as illustrated in FIG. 8. Thus, when the protective film PF is adhered, there is no gap between the scribe line SL and the protective film PF, and the protective film PF is in closer contact with the scribe line SL as illustrated in FIG. 8. The area of close contact between the protective film PF and the scribe line SL thus further increases to more surely prevent ingress of water and the etching solution from the outer peripheral portion of the wafer into the scribe line SL, so that damage of the semiconductor wafer WH can be suppressed.

While the protective film PF is disposed over the photosensitive polyimide film PI in each of FIGS. 7 and 8, depending on the semiconductor wafer, the photosensitive polyimide film PI is not disposed, and the protective film PF is directly adhered to the semiconductor wafer.

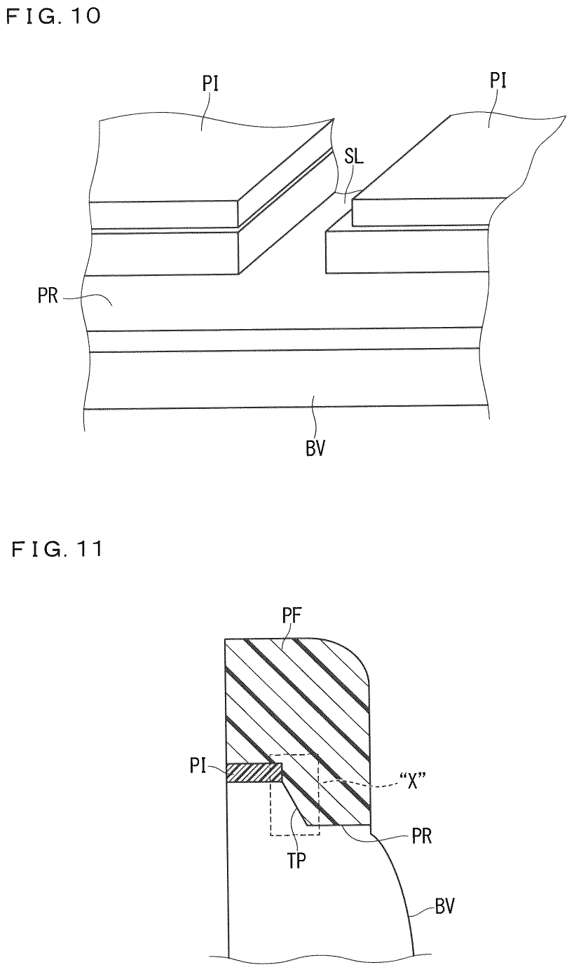

When the photosensitive polyimide film PI is disposed, the grinding region PR is formed after the photosensitive polyimide film PI is formed over the semiconductor wafer WH. FIG. 10 is a partial perspective view illustrating the outer periphery of the semiconductor wafer WH after the grinding region PR is formed, and the grinding region PR is formed to have the same depth as the scribe lines SL to eliminate the step between the grinding region PR and the bottom surface of each of the scribe lines SL.

### Embodiment 3

While a step portion between the grinding region PR provided at the outer periphery of the semiconductor wafer WH and the upper surface of the semiconductor wafer WH is vertical in each of Embodiments 1 and 2, a step portion for the grinding region PR has an inclined tapered surface in the semiconductor wafer WH according to Embodiment 3.

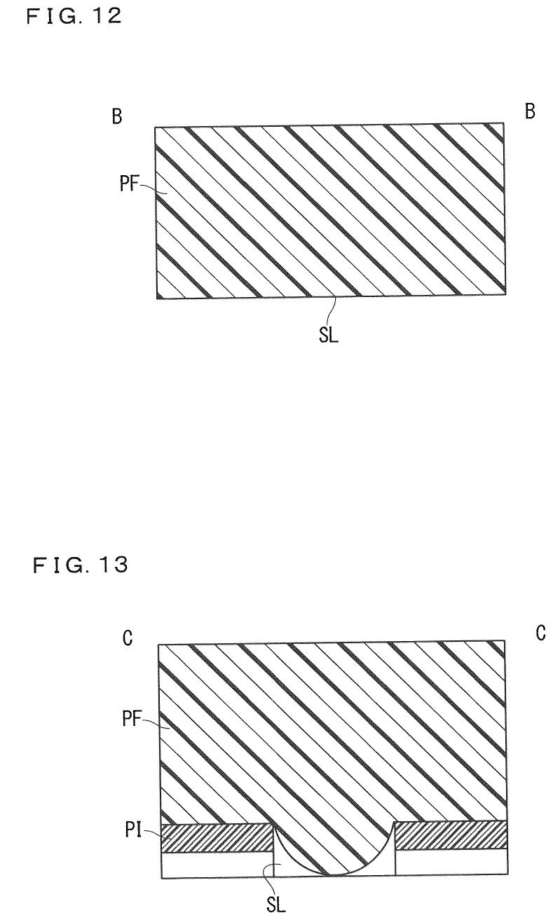

FIG. 11, FIG. 12, and FIG. 13 are cross-sectional views respectively taken along the line A-A, the line B-B, and the line C-C of FIG. 1. In FIGS. 11 to 13, the same components as those of the semiconductor wafer WH according to Embodiment 1 described with reference to FIGS. 2 to 4 bear the same reference signs as those of the same components, and redundant description is omitted.

As illustrated in FIG. 11, the step portion between the upper surface of the semiconductor wafer WH and the grinding region PR has a tapered surface TP, the protective film PF is in close contact with the tapered surface TP, and there is no gap between them.

The grinding region PR is provided to have the same depth as the scribe lines SL, so that the step between the grinding region PR and the bottom surface of each of the scribe lines SL can be eliminated as illustrated in FIG. 12. Thus, when the protective film PF is adhered, there is no gap between the scribe line SL and the protective film PF, and the protective film PF is in closer contact with the scribe line SL as illustrated in FIG. 12.

The area of close contact between the protective film PF and the scribe line SL thus further increases to more surely prevent ingress of water and the etching solution from the outer peripheral portion of the wafer into the scribe line SL, so that damage of the semiconductor wafer WH can be suppressed.

While the protective film PF is disposed over the photosensitive polyimide film PI in each of FIGS. 11 to 13, depending on the semiconductor wafer, the photosensitive polyimide film PI is not disposed, and the protective film PF is directly adhered to the semiconductor wafer.

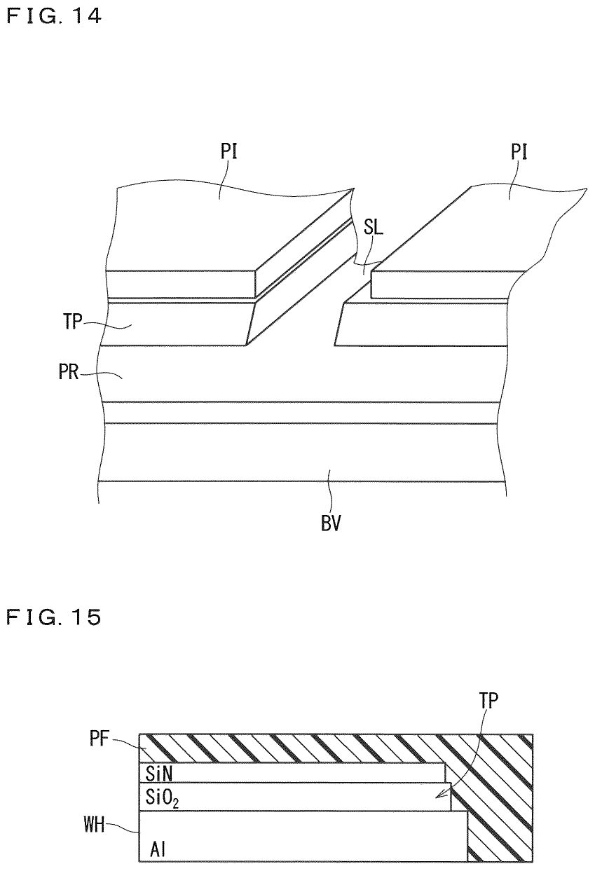

When the photosensitive polyimide film PI is disposed, the grinding region PR is formed after the photosensitive polyimide film PI is formed over the semiconductor wafer WH. FIG. 14 is a partial perspective view illustrating the outer periphery of the semiconductor wafer WH after the grinding region PR is formed, and the grinding region PR is formed to have the same depth as the scribe lines SL to eliminate the step between the grinding region PR and the bottom surface of each of the scribe lines SL. The step portion between the upper surface of the semiconductor wafer WH and the grinding region PR has the tapered surface TP, the protective film PF is in close contact with the tapered surface TP with no gap between them, and an effect of preventing ingress of water and the etching solution into the scribe lines SL is further enhanced.

Multilayer structures of the semiconductor devices are sometimes exposed to the surface of the semiconductor wafer WH by forming the tapered surface TP. FIG. 15 is a diagram schematically showing a cross section of a portion having the tapered surface TP of the semiconductor wafer WH. As illustrated in FIG. 15, a semiconductor device sometimes includes a protective layer including a silicon oxide (SiO₂) layer and/or a silicon nitride (SiN) layer to protect a wiring layer of aluminum (Al) and the like.

When an end surface of a multilayer structure is exposed stepwise by providing the tapered surface TP, a surface area of each layer at the tapered surface TP increases to eventually improve adhesion of the protective film PF.

A force of adhesion to the protective film PF can increase due to a material of each layer and surface irregularities of each layer. That is to say, when layers are formed of different materials as illustrated in FIG. 15, the layers have different surface intermolecular interactions and can have different forces of adhesion to the protective film PF. For example, when the protective film PF is formed of the polyacrylic-based resin, adhesion to aluminum is good. When the layers have different surface irregularities, a layer having a large surface irregularity has enhanced adhesion to the protective film PF due to an anchoring effect.

As described above, when the multilayer structures of the semiconductor devices are exposed to the surface of the semiconductor wafer WH by forming the tapered surface TP, adhesion to the protective film PF can further be improved.

### Modifications

While the semiconductor wafer WH according to Embodiment 3 described above has a configuration in which the step portion for the grinding region PR has a single-step tapered surface TP, the tapered surface TP is not limited to the single-step tapered surface and may be a multi-step tapered surface.

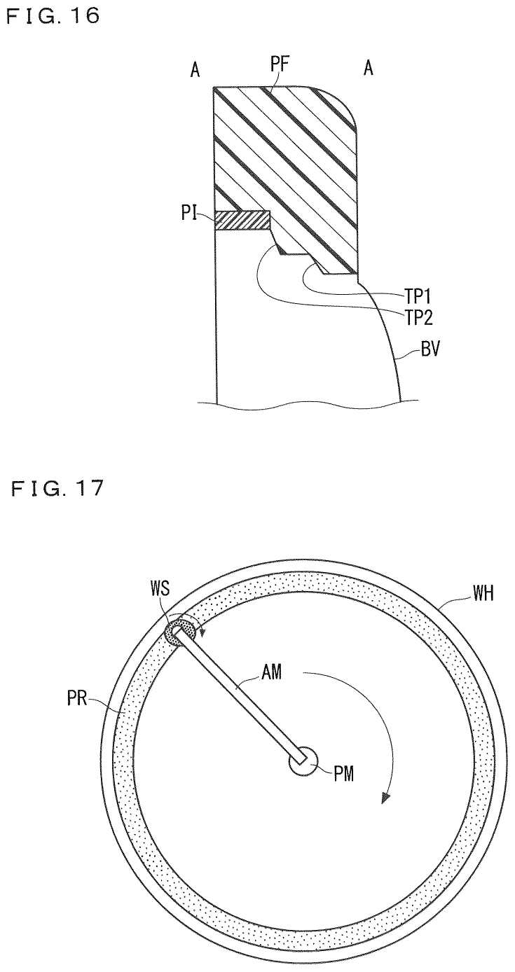

FIG. 16 is a diagram corresponding to FIG. 11, and the step portion between the upper surface of the semiconductor wafer WH and the grinding region PR has a double-step tapered surface including a tapered surface TP1 and a tapered surface TP2. Also in this case, the protective film PF is in close contact with the tapered surfaces TP1 and TP2 with no gap between them.

The multi-step tapered surface can suppress a steep angle of the tapered surface, increase the area of contact with the protective film PF, and further enhance adhesion of the protective film PF.

Adhesion to the protective film PF can further be improved when the multilayer structures of the semiconductor devices are exposed to the surface of the semiconductor wafer WH by forming the multi-step tapered surface.

### Embodiment 4

A semiconductor wafer processing method according to Embodiment 4 will be described below. Embodiment 4 relates to a method of processing the semiconductor wafer WH according to each of Embodiments 1 and 2, and a step of forming the grinding region PR will be described.

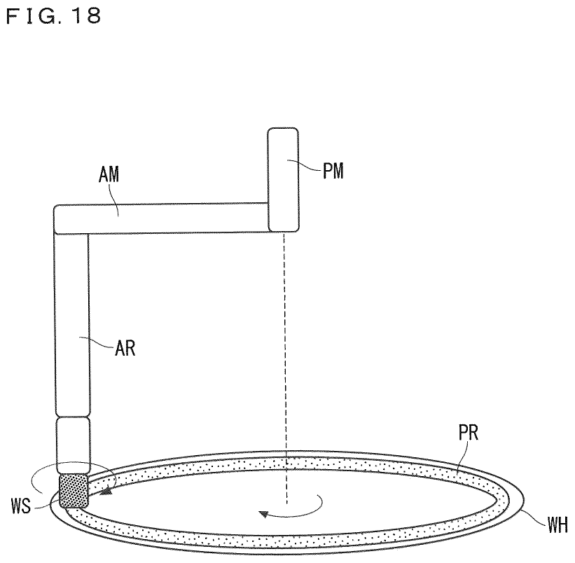

FIG. 17 is a plan view illustrating a state of mounting, over a rotation stage (not illustrated) of a grinding apparatus, the semiconductor wafer WH including the semiconductor devices and the like over the front surface thereof and including the photosensitive polyimide film, and FIG. 18 is a side view thereof.

The grinding apparatus includes a support shaft PM disposed above a center of rotation of the rotation stage, an arm AM extending from the support shaft PM in a direction of a radius of the rotation stage, and a rotating shaft AR extending vertically from an end of the arm AM toward the semiconductor wafer WH. A grinding wheel WS has been attached to a leading end of the rotating shaft AR and is freely rotated by rotation of the rotating shaft AR.

The grinding region PR is formed using the above-mentioned grinding apparatus by the following method. First, the semiconductor wafer WH is mounted over the rotation stage (not illustrated) of the grinding apparatus.

Next, the grinding wheel WS is disposed above a region inside the wafer bevel portion BV and outside the polyimide region where the photosensitive polyimide film is disposed.

Next, the grinding wheel WS is brought into contact with the semiconductor wafer WH while the rotating shaft AR is rotated with the semiconductor wafer WH being spun by rotation of the stage to form the grinding region PR having a shallower depth than or the same depth as the scribe lines at the outer periphery of the wafer.

In this case, grinding can surely be performed by setting a rotation speed of the grinding wheel WS to a speed greater than a rotation speed of the semiconductor wafer.

The rotating shaft AR is movable in the direction of the radius of the rotation stage and is also movable in a direction perpendicular to the rotation stage, and a depth of the grinding region PR can be set by moving the rotating shaft AR in the perpendicular direction while pressing the rotating shaft AR against the semiconductor wafer WH.

### Embodiment 5

A semiconductor wafer processing method according to Embodiment 5 will be described below. Embodiment 5 relates to a method of processing the semiconductor wafer WH according to Embodiment 3, and a step of forming the grinding region PR will be described.

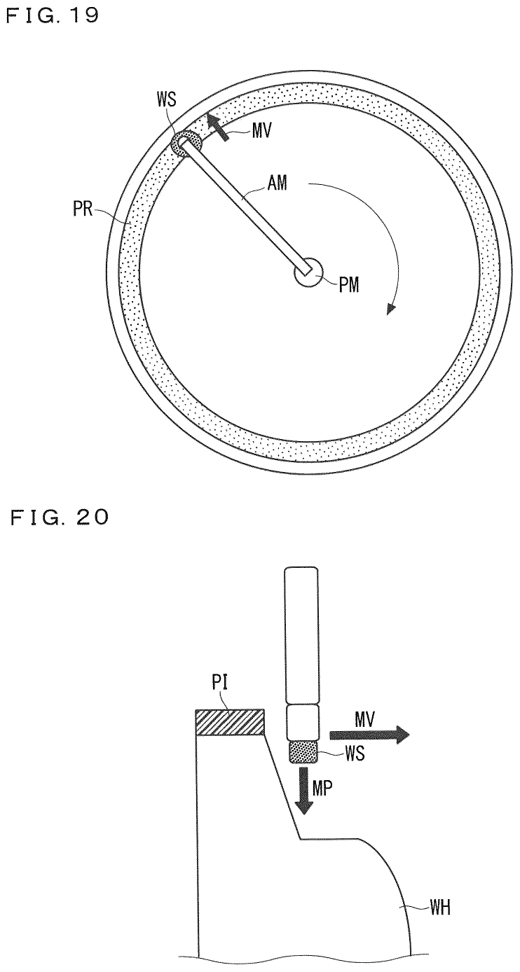

FIG. 19 is a plan view illustrating a state of mounting, over the rotation stage (not illustrated) of the grinding apparatus, the semiconductor wafer WH including the semiconductor devices and the like over the front surface thereof and including the photosensitive polyimide film. FIG. 19 is basically the same as FIG. 17 for Embodiment 4, and the same components as those in FIG. 17 bear the same reference signs as those of the same components, and redundant description is omitted.

While a method of disposing the grinding wheel WS above the region inside the wafer bevel portion BV and outside the polyimide region where the photosensitive polyimide film is disposed and bringing the grinding wheel WS into contact with the semiconductor wafer WH while rotating the rotating shaft AR with the semiconductor wafer WH being spun by rotation of the stage to form the grinding region PR has been described in Embodiment 4, in Embodiment 5, the grinding wheel WS is moved toward the outer periphery of the semiconductor wafer WH as indicated by an arrow MV in FIG. 19 to cause the step portion between the upper surface of the semiconductor wafer WH and the grinding region PR to have the tapered surface TP as illustrated in FIG. 11.

FIG. 20 is a diagram schematically showing a state of processing a boxed region “X” in FIG. 11, and the grinding wheel WS is moved in the perpendicular direction indicated by an arrow MP while being moved toward the outer periphery of the semiconductor wafer WH as indicated by the arrow MV to form a straight tapered surface TP. In this case, an amount of movement in the direction of the arrow MP (an amount of grinding) of the grinding wheel WS is changed in response to an amount of movement in the direction of the arrow MV of the grinding wheel WS by numerical operation.

As one example of the numerical operation, a circumferential speed (m/s)=an outer diameter (m) of the grinding wheel×revolutions per minute (rpm) of the grinding wheel×3.14÷60 is used. The circumferential speed is obtained from the revolutions per minute and the outer diameter of the grinding wheel, and an amount of grinding per second at the speed is determined, so that the straight tapered surface TP can be formed by controlling movement of the grinding wheel WS so that the circumferential speed changes linearly from a graph having time(s) plotted along a horizontal axis and the circumferential speed (m/s) plotted along a vertical axis.

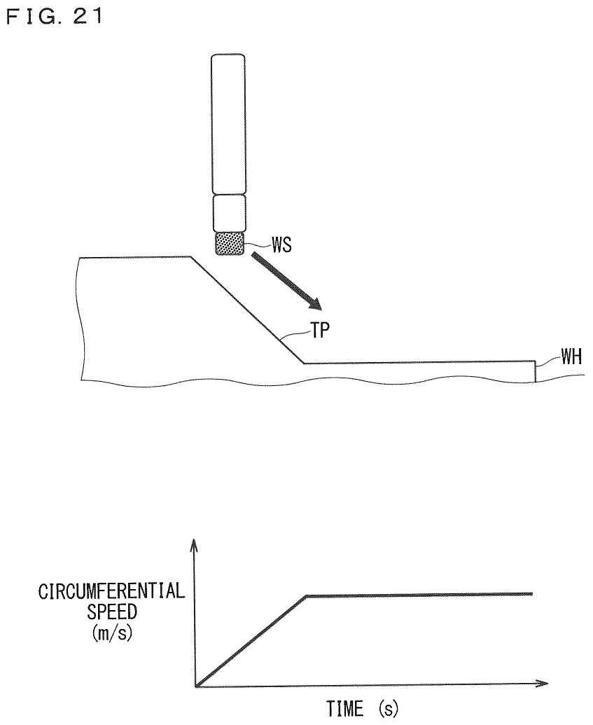

FIG. 21 shows a cross section of the tapered surface TP of the semiconductor wafer WH and control characteristics of the grinding wheel WS having the time(s) plotted along the horizontal axis and the circumferential speed (m/s) plotted along the vertical axis.

### Modifications

While the method of forming the straight tapered surface TP has been described in the semiconductor wafer processing method according to Embodiment 5 described above, the tapered surface TP is not limited to the straight tapered surface and may be a curved tapered surface.

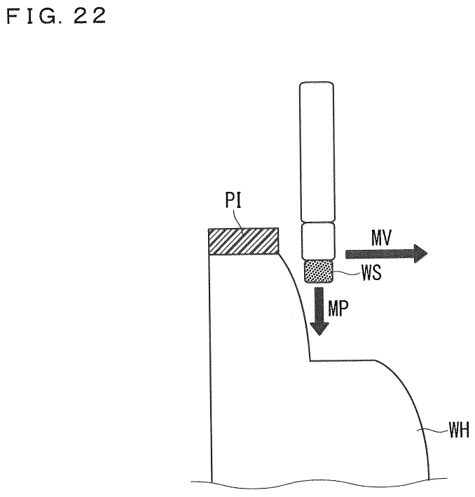

FIG. 22 is a diagram illustrating one example of a curved tapered surface TPX and corresponding to FIG. 20. By forming a gently curved tapered surface TPX as illustrated in FIG. 22, adhesion of the protective film PF is enhanced. The curved tapered surface TPX can be formed by controlling movement of the grinding wheel WS so that the circumferential speed changes curvilinearly with the time(s) plotted along the horizontal direction and the circumferential speed (m/s) plotted along the vertical direction.

Embodiments of the present disclosure can freely be combined with each other and can be modified or omitted as appropriate within the scope of the present disclosure.

The present disclosure described above will collectively be described below as appendices.

### Appendix 1

A semiconductor wafer comprising:
a plurality of semiconductor devices;
a plurality of scribe lines to divide the plurality of semiconductor devices into a plurality of semiconductor chips; and
a grinding region provided along an outer peripheral portion and having a depth that is shallower than or the same as depths of the scribe lines.

### Appendix 2

The semiconductor wafer according to Appendix 1, wherein
the grinding region is provided inside a wafer bevel portion and outside a polyimide region where a photosensitive polyimide film is disposed.

### Appendix 3

The semiconductor wafer according to Appendix 1 or 2, wherein
a step portion between an upper surface of the semiconductor wafer and the grinding region has a tapered surface.

### Appendix 4

The semiconductor wafer according to Appendix 1 or 2, wherein
a step portion between an upper surface of the semiconductor wafer and the grinding region has a multi-step tapered surface.

### Appendix 5

A semiconductor wafer processing method of processing the semiconductor wafer according to Appendix 1, the semiconductor wafer processing method comprising:
(a) mounting the semiconductor wafer to a rotation stage;
(b) disposing a freely rotated grinding wheel above the outer peripheral portion of the semiconductor wafer; and
(c) bringing the grinding wheel into contact with the semiconductor wafer while rotating the grinding wheel with the semiconductor wafer being spun by rotation of the rotation stage to grind the outer peripheral portion to form the grinding region.

### Appendix 6

A semiconductor wafer processing method of processing the semiconductor wafer according to Appendix 3, the semiconductor wafer processing method comprising:
(a) mounting the semiconductor wafer to a rotation stage;
(b) disposing a freely rotated grinding wheel above the outer peripheral portion of the semiconductor wafer; and
(c) bringing the grinding wheel into contact with the semiconductor wafer while rotating the grinding wheel with the semiconductor wafer being spun by rotation of the rotation stage and moving the grinding wheel toward an outer periphery of the semiconductor wafer to grind the outer peripheral portion to form the grinding region so that the step portion has the tapered surface.

### Appendix 7

The semiconductor wafer processing method according to Appendix 6, wherein
in step (c), an amount of grinding of the grinding wheel is changed in response to an amount of movement of the grinding wheel toward the outer periphery by numerical operation to make the tapered surface straight.

### Appendix 8

The semiconductor wafer processing method according to Appendix 6, wherein
in step (c), an amount of grinding of the grinding wheel is changed in response to an amount of movement of the grinding wheel toward the outer periphery by numerical operation to make the tapered surface curved.

### Appendix 9

The semiconductor wafer processing method according to Appendix 5 or 6, wherein
in step (c), the outer peripheral portion is ground with a rotation speed of the grinding wheel being set to a speed greater than a rotation speed of the semiconductor wafer.

While the disclosure has been shown and described in detail, the foregoing description is in all aspects illustrative and not restrictive. It is therefore understood that numerous modifications and variations can be devised.

What is claimed is:

1. A semiconductor wafer comprising:
a plurality of semiconductor devices;
a plurality of scribe lines to divide the plurality of semiconductor devices into a plurality of semiconductor chips; and
a grinding region provided along an outer peripheral portion and having a depth that is shallower than or the same as depths of the scribe lines.

2. The semiconductor wafer according to claim 1, wherein
the grinding region is provided inside a wafer bevel portion and outside a polyimide region where a photosensitive polyimide film is disposed.

3. The semiconductor wafer according to claim 1, wherein
a step portion between an upper surface of the semiconductor wafer and the grinding region has a tapered surface.

4. The semiconductor wafer according to claim 1, wherein
a step portion between an upper surface of the semiconductor wafer and the grinding region has a multi-step tapered surface.

5. A semiconductor wafer processing method of processing the semiconductor wafer according to claim 1, the semiconductor wafer processing method comprising:
(a) mounting the semiconductor wafer to a rotation stage;
(b) disposing a freely rotated grinding wheel above the outer peripheral portion of the semiconductor wafer; and
(c) bringing the grinding wheel into contact with the semiconductor wafer while rotating the grinding wheel with the semiconductor wafer being spun by rotation of the rotation stage to grind the outer peripheral portion to form the grinding region.

6. A semiconductor wafer processing method of processing the semiconductor wafer according to claim 3, the semiconductor wafer processing method comprising:
(a) mounting the semiconductor wafer to a rotation stage;
(b) disposing a freely rotated grinding wheel above the outer peripheral portion of the semiconductor wafer; and
(c) bringing the grinding wheel into contact with the semiconductor wafer while rotating the grinding wheel with the semiconductor wafer being spun by rotation of the rotation stage and moving the grinding wheel toward an outer periphery of the semiconductor wafer to grind the outer peripheral portion to form the grinding region so that the step portion has the tapered surface.

7. The semiconductor wafer processing method according to claim 6, wherein
in step (c), an amount of grinding of the grinding wheel is changed in response to an amount of movement of the grinding wheel toward the outer periphery by numerical operation to make the tapered surface straight.

8. The semiconductor wafer processing method according to claim 6, wherein
in step (c), an amount of grinding of the grinding wheel is changed in response to an amount of movement of the grinding wheel toward the outer periphery by numerical operation to make the tapered surface curved.

9. The semiconductor wafer processing method according to claim 5, wherein
in step (c), the outer peripheral portion is ground with a rotation speed of the grinding wheel being set to a speed greater than a rotation speed of the semiconductor wafer.

10. The semiconductor wafer processing method according to claim 6, wherein
in step (c), the outer peripheral portion is ground with a rotation speed of the grinding wheel being set to a speed greater than a rotation speed of the semiconductor wafer.
